(19) United States
(12) Patent Application Publication
(10) Pub. No.: US 2025/0151315 A1
(43) Pub. Date: May 8, 2025

(54) A TRANSISTOR AND A METHOD FOR THE MANUFACTURE OF A TRANSISTOR

(71) Applicant: Paragraf Limited, Somersham (GB)

(72) Inventors: Robert Wallis, Somersham (GB); Zhichao Weng, Somersham (GB); Oliver Fenwick, Somersham (GB); William Gillin, Somersham (GB); Ivor Guiney, Somersham (GB)

(73) Assignee: Paragraf Limited, Somersham (GB)

(21) Appl. No.: 18/837,634

(22) PCT Filed: Feb. 8, 2023
(86) PCT No.: PCT/EP2023/053059

§ 371 Date: Aug. 12, 2024

(30) Foreign Application Priority Data
Feb. 16, 2022 (GB) 2202053.1

(51) Int. Cl. H10D 30/47; H10D 30/01; H10D 62/80; H10D 64/23; H10D 64/62

(52) U.S. Cl. CPC H10D 30/481; H10D 30/017; H10D 62/882; H10D 64/251; H10D 64/62

(57) ABSTRACT

There is provided a transistor comprising: a graphene layer structure provided on a non-metallic surface of a substrate, the graphene layer structure having an insulating cap; a source contact provided in contact with a first edge of the graphene layer structure; an insulator provided in contact with an opposite, second edge of the graphene layer structure; a drain contact provided in contact with the insulator, whereby there is a distance of least separation between the drain contact and the graphene layer structure along the second edge of the graphene layer structure and through the insulator; and a gate contact provided (i) over the graphene layer structure and separated therefrom by the insulating cap and/or (ii) under the graphene layer structure and separated therefrom by substrate.

The present invention relates to a transistor and a method for the manufacture of a transistor. In particular, the present invention relates to a graphene transistor comprising source, drain and gate contacts, and a tunnel junction whereby the drain contact is separated from the graphene via an insulator. The method specifically comprises depositing a drain contact on an insulator and over a graphene layer structure thereby separating the drain contact from the graphene.

Graphene field-effect transistors for logic applications have been hampered by the finite conductivity of graphene at the Dirac point and the inability to prevent electron flow laterally through potential barriers in the graphene due to Klein tunnelling. These considerations present a fundamental problem for the development of graphene-based integrated circuits, as the on/off ratio is limited to values below 10, where values above 10,000 are generally required. It is possible to open a bandgap in graphene via a variety of techniques, such as using bilayer graphene, nanoribbons, or chemical derivatives, but it remains challenging to achieve good current on/off ratios without compromising the quality of the graphene. One alternative in the art is to use two-dimensional materials such as transition metal dichalcogenides (TMDCs) though their carrier mobilities are too low for practical devices.

One method for overcoming the limitations in graphene-based transistors relies on a vertical heterostructure and modification of the work function of the graphene as a means to modulate current flow (so-called barrier transistors or barristors). An alternative is to use an ultra-thin tunnelling barrier between source and drain graphene electrodes, allowing the current through the barrier to be modulated via the use of a gate. However, there are considerable challenges around fabricating such a tunnel barrier without leakage and with the correct thickness to facilitate tunnelling. Examples of such devices are described in “Field-Effect Tunneling Transistor Based on Vertical Graphene Heterostructures” Science 2012, 335, 6071, “Vertical field-effect transistor based on graphene-WS₂ heterostructures for flexible and transparent electronics” Nature Nanotechnology 2012, 8, 100 along with “Fowler-Nordheim tunneling characteristics of graphene/hBN/metal heterojunctions” Journal of Applied Physics 2019, 125, 084902. In these devices, the tunnel barrier (e.g. hexagonal boron nitride) is positioned underneath one of the source or drain contacts of the transistor, and tunnelling current travels vertically through the barrier from the graphene to the drain.

WO 2015/050328 A1 relates to a semiconductor device, such as a planar type graphene barristor, which may include a source, a drain, a semiconductor element between the source and the drain, and a graphene layer that is provided on the source and the semiconductor element and is spaced apart from the drain. US 2010/0258787 A1 relates to a field effect transistor using graphene in a channel layer. KR 2017-0130646 A relates to a phototransistor including a channel using graphene. US2014/0097404 A1 relates to memory cells, memory devices, and memory arrays including graphene switching devices. CN 104409498 A relates to high-frequency semiconductor devices. US 2012/0261645 A1 relates to a graphene device having a structure in which a physical gap is provided so that the off-state current of the graphene device can be significantly reduced without having to form a band gap in the graphene.

The present inventors developed the present invention seeking to overcome the problems with known graphene-based transistors to provide an improved and more reliable device together with a method for the manufacture of such a transistor, in particular a method which may be used to mass manufacture an array of devices on a single common substrate. At the very least the inventors have found a commercially useful alternative.

In a first aspect of the present invention, there is provided a transistor comprising:
a graphene layer structure provided on a non-metallic surface of a substrate, the graphene layer structure having an insulating cap;
a source contact provided in contact with a first edge of the graphene layer structure;
an insulator provided in contact with an opposite, second edge of the graphene layer structure;
a drain contact provided in contact with the insulator, whereby there is a distance of least separation between the drain contact and the graphene layer structure along the second edge of the graphene layer structure and through the insulator; and
a gate contact provided (i) over the graphene layer structure and separated therefrom by the insulating cap and/or (ii) under the graphene layer structure and separated therefrom by the substrate.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous. It is intended that the features disclosed in relation to the transistor may be combined with those disclosed in relation to the method and vice versa. Accordingly, it is preferred that the transistor is obtainable by the method and also preferable that the method is one of manufacturing the transistor described herein.

The present invention relates to a transistor, specifically a transistor comprising a graphene layer structure which serves as an active channel in the transistor (i.e. in use there is a flow of current through the graphene, with the graphene forming a channel region). The transistor may therefore be referred to as a graphene transistor or a graphene-based transistor, preferably a graphene field-effect transistor which is a type of transistor which uses an electric field to modulate the flow of current. Field-effect transistors are known in the art and comprise a gate contact (or electrode) to which a voltage may be applied which in turn modulates the conductivity between the source and drain contacts (electrodes).

The present transistor further comprises a tunnel barrier and, as will be appreciated for such a transistor, it follows that, in use, under a first bias condition, a first gate voltage permits a flow of electrons from the source contact, across the graphene layer structure from the first edge to the second edge, and via the insulator to the drain electrode and, under a second bias condition, a second gate voltage inhibits a flow of electrons across the graphene layer structure. In particular, the second gate voltage inhibits flow of electrons across the graphene layer structure by inhibiting the tunnelling through the dielectric barrier as described herein.

The transistor comprises a graphene layer structure, said graphene layer structure provided on a non-metallic surface of a substrate and having an insulating cap.

Graphene is a very well-known two-dimensional material referring to an allotrope of carbon comprising a single layer of carbon atoms in a hexagonal lattice. A graphene layer structure, as used herein, refers to graphene which consists of one or more layers of graphene (also referred to as graphene monolayers or graphene sheets). Therefore, a graphene layer structure encompasses a single layer of graphene (i.e. a graphene monolayer), or multilayer graphene consisting of 2 or 3 graphene monolayers, for example. The graphene layer structure may be doped or undoped. A monolayer of graphene has unique electronic properties associated with the “Dirac cone” band structure of a single graphene layer structure and is most preferred. However, as discussed above, this lack of band structure is a problem with monolayer graphene when seeking to provide the desired on/off ratios needed for transistors. In order to achieve such ratios, the present transistor comprises a tunnel barrier between the graphene and drain. Whilst of pseudo-infinite size in two-dimensions, the graphene layer structure is patterned (or shaped) to a suitable size for a transistor (as is known in the art).

Whilst the present invention is described with respect to a graphene layer structure, it will be appreciated that equivalent two-dimensional materials may also be used in its place so as to achieve substantially the same effect. As described for graphene, monolayer silicene (a silicon equivalent to graphene), monolayer phosphorene (an all-phosphorus equivalent to graphene) and monolayer TMDCs such as MoS₂ are preferred two-dimensional materials for a transistor.

The graphene layer structure is provided on a non-metallic surface of a substrate. Preferably, the surface is an electrically insulative surface (for example, a substrate may be a silicon substrate having a silicon dioxide surface). By using an electrically insulative surface, this avoids the risk of current flow through the substrate (for example in accordance with the mechanism of a graphene barristor) and is therefore particularly preferred. As described further herein, the present transistor operates by tunnelling of electrons through the relatively thin barrier adjacent (and extending along) an edge of the graphene. The substrate may also be a CMOS wafer which may be silicon based and have associated circuitry embedded within the substrate. A substrate may also comprise one or more layers, such as in the “back-gated” embodiments described herein. A substrate may be a composite substrate comprising one or more layers. For example, a substrate may comprise a non-metallic layer which provides the non-metallic surface, and a conductive layer (for example, silicon on insulator (SOI) substrates such as a silicon substrate having a silicon oxide layer). The conductive layer can serve as the gate contact. Preferably, the non-metallic surface upon which the graphene layer structure is provided is silicon (Si), silicon carbide (SIC), silicon nitride (Si₃N₄), silicon dioxide (SiO₂), sapphire (Al₂O₃), aluminium gallium oxide (AGO) hafnium dioxide, zirconium dioxide, yttria-stabilised hafnia (YSH), yttria-stabilised zirconia (YSZ), magnesium aluminate (MgAl₂O₄), yttrium orthoaluminate (YAlO₃), strontium titanate (SrTiO₃), cerium oxide (Ce₂O₃), scandium oxide (SC₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN, cubic boron nitride (c-BN) and/or a III/V semiconductor such as aluminium nitride (AlN) and gallium nitride (GaN).

Such substrate surfaces are particularly suited for the growth of graphene thereon by CVD. By providing graphene directly on the substrate surface (i.e. without transferring the graphene from a growth substrate, typically copper), graphene of much higher quality and uniformity may be provided as described herein with regard to the method. Accordingly, it is preferred that the graphene is provided on the substrate surface by CVD, particularly by a method in accordance with WO 2017/029470, the contents of which is incorporated herein by reference in its entirety. Such a method is particularly suited for growth on non-metallic surfaces of substrates. The method of WO 2017/029470 is ideally performed using an MOCVD reactor. Whilst MOCVD stands for metal organic chemical vapour deposition due to its origins for the purposes of manufacturing semiconductor materials such as AlN and GaN from metal organic precursors such as AlMe₃ (TMAI) and GaMe₃ (TMGa), such apparatus and reactors are well known and understood to those skilled in the art as being suitable for use with non-metal organic precursors. As used herein, growing may be considered synonymous with forming, synthesising, manufacturing, and producing.

The insulating cap is provided on the graphene layer structure. The insulating cap is a layer of insulator (i.e. insulating material, preferably a dielectric). The insulator being provided as a cap serves to share a continuous edge with that of the graphene layer structure directly beneath. In a preferred embodiment as described herein, the insulating cap is provided by evaporation deposition through a mask onto an unpatterned graphene layer structure. The areas of the exposed graphene layer structure not covered by the insulating cap may then be removed thereby patterning the graphene layer structure with the same pattern as that of the insulating cap. Preferably, the graphene is removed using plasma etching, e.g. oxygen plasma etching. Preferably, the insulating cap has a trapezoidal cross-section (i.e. in a plane orthogonal to the plane of the substrate) since such a shape arises from deposition through a mask. A trapezoidal cross-section is unexpectedly advantageous as this allows the cap to have a minimal thickness at the edges of the graphene. This permits more uniform growth of the insulator layer described hereinbelow and therefore, a more uniform and reliable separation of the drain contact from the edge of the graphene layer structure.

Preferably, the thickness of the insulating cap is at least 3 nm, preferably at least 4 nm and more preferably at least 5 nm. Generally, the thickness of the insulating cap is no more than 50 nm, such as up to 20 nm, preferably up to 10 nm. The upper surface of the insulating cap is generally parallel with the plane of the underlying graphene and substrate and the thickness is that measured in this area (i.e. excluding the regions by the edges whereby the insulating cap may have sloped sides resulting from the deposition method). Typically, in embodiments whereby the edge of the insulating cap is not substantially equal to 90° to the plane of the substrate, the angle of contact of the shaped cap is at least 30°, preferably at least 45°.

The present invention is particularly suitable for the mass manufacture of an array of transistors on a common substrate. An array of insulator caps may be provided on a common graphene layer structure (itself on a single substrate) and the exposed portions of the graphene layer structure etched to provide an array of graphene layer structures, each having an insulator cap. Accordingly, the above benefit associated with the more uniform insulator layer applied equally for the uniformity for each device in the array such that the electronic characteristics of each device are consistent across the array, which is essential for the mass manufacture of graphene-based devices. For example, a common substrate may be a conventionally sized substrate (also referred to in the art as wafers), such as at least 2 inches in diameter (51 mm), preferably at least 6 inches (150 mm).

Suitable materials for the insulating materials (i.e. for the insulating cap and any other layer of insulator described herein) are dielectric materials. The dielectric constant (k) of a dielectric material may be greater than 2, preferably greater than 3 and even more preferably greater than 4 (when measured at 1 KHz at room temperature). Preferably, the insulating cap comprises alumina, silica, hafnia, titania, yttria, zirconia, yttria-stabilised zirconia, and/or silicon nitride. Such materials are particularly suitable for evaporation deposition.

The transistor will now be described further with reference to source, drain and gate contacts. The function of each contact will be understood by those skilled in the art, for example, whereby a gate contact is located so as to be able to modulate the current flow between the source and drain upon application of a gate voltage. Whilst the size and composition of the three contacts (source, gate and drain) may be the same or different, the terminology used will be understood by the person skilled in the art as specific contacts for use in incorporation into an electrical device. In other words, once electrical connections are provided on the contacts, the skilled person would understand how these are subsequently circuited to enable operation of the transistor. In accordance with the present transistor, in view of the insulating cap covering the surface of the graphene layer structure, a source contact is provided in contact with a first edge of a graphene layer structure. Charge injection into the graphene layer structure is particularly improved at the graphene edges. Particularly where metal ohmic contacts are used, this avoids the undesired doping of the graphene by avoiding depositing the metal on the graphene surface.

Typically, a patterned graphene layer structure will have one continuous outer edge defining a two-dimensional shape (e.g. a square, rectangle or circle). A first edge of the graphene layer structure as described herein serves to differentiate over a second edge which is sufficiently far removed from the first edge such that current flows from the source contact at the first edge to the opposite second edge (and via the insulator to the drain contact). Additionally, as mentioned above, application of a voltage to the gate contact allows a user to modulate the current flow from the first edge to the second edge. Typically, the graphene layer structure may have a rectangular shape whereby the source and drain are located by opposite parallel edges though it will be appreciated that other configurations are suitable. Accordingly, source and drain contacts are typically located at distal portions from the “centre of mass” of the graphene layer structure.

An insulator (i.e. a layer in addition to the insulating cap) is provided in contact with an opposite, second edge of the graphene layer structure. Preferably, the insulator is provided as a continuous layer over (and directly on) the source, the insulating cap and at least a portion of the substrate so as to completely cover these features. This continuous layer therefore covers and protects the edge(s) of the graphene layer structure from atmospheric contamination which may help to avoid drift in the charge carrier density.

The inventors have advantageously found that by providing an insulator in contact with the second edge of the graphene layer structure, the insulator may serve to separate a drain contact from the graphene edge to provide a tunnel junction in a relatively “lateral” configuration. This is in contrast to known “vertical” tunnel junctions of graphene-based transistors. The inventors have found that growth of suitable insulators for tunnel junctions is particularly challenging. It is necessary for the insulator to be sufficiently thin so as to allow tunnelling of charge carriers across the barrier whilst also having sufficient quality to prevent current leakage through defects. This cannot be achieved by the insulator cap.

A drain contact is provided in contact with the insulator, whereby there is a distance of least separation between the drain contact and the graphene layer structure along the second edge of the graphene layer structure and through the insulator. That is, the drain contact is at its closest to the graphene layer structure along the second edge, the drain being separated from the graphene by the insulator. The length over which the graphene layer structure is separated from the drain contact by the distance of least separation is not particularly limited, and may be from 1 nm to 100 μm, for example, and/or the drain contact may extend the full length of the second edge or a portion thereof. Preferably, the insulator is provided as a continuous layer over the source, the insulating cap and at least a portion of the substrate such that it is preferred that the drain contact is provided on the insulator layer. The drain contact may also extend so as to overlay the surface of the graphene layer structure being provided on the insulating cap, though the separation distance to the graphene surface will be greater than the distance of least separation to the graphene edge due to the presence of the insulating cap. In order to function as a tunnel junction, the distance of least separation is preferably less than 10 nm, more preferably less than 5 nm, even more preferably less than 4 nm. The thickness of the insulator layer and the distance of least separation depends on the material chosen and the method of deposition. As will be appreciated, a material with a smaller bandgap allows a thicker tunnel barrier for a constant tunnelling current. Preferably, the distance of least separation is from 1 to 5 nm, for example from 1 to 4 nm.

In a preferred embodiment as described herein, the insulator is provided by atomic layer deposition (ALD). Such a method permits the conformal growth of such thin barrier layers (i.e. of less than 10 nm). Moreover, the inventors have found that in the absence of nucleation sites on the surface of the two-dimensional material graphene, ALD directly on the surface of graphene is challenging whereas ALD across the insulating cap and the substrate is more effective. Accordingly, it is preferred that the insulator comprises alumina, silica, hafnia, titania, yttria, zirconia and/or yttria-stabilised zirconia, such materials being particularly suited for ALD. As a result of the conformal deposition and growth, the thickness of the insulator layer may be substantially uniform across the entire device such that a suitable distance of least separation can be provided by depositing a layer having a thickness of from 1 to 5 nm. However, provided it is sufficiently thin (such as less than 10 nm) between the second edge and the drain to provide a suitable tunnel barrier, in other embodiments, the thickness of the insulator elsewhere may be greater than the distance of least separation.

In some preferred embodiments, the distance of least separation may be greater provided that the insulator layer provides a suitable tunnel barrier (for example in embodiments wherein the non-metallic surface is electrically insulative thereby avoiding alternative current pathways). Typically the distance of least separation is still less than about 50 nm, preferably less than about 30 nm.

As described herein, the insulator layer may comprise (or consist of) multiple insulator materials. In some embodiments, the insulator layer may be formed of a bilayer, such as one formed by evaporated and oxidised metal followed by ALD deposition of a second layer. By way of example, the insulator comprises a layer (i.e. a lower layer or a sub-layer) formed of titanium or aluminium oxide and a layer (i.e. an upper layer or a further sub-layer) thereon formed of aluminium oxide. Such an insulator may be formed by deposition of a layer of titanium or aluminium metal followed by oxidation to form the oxide and ALD deposition of a layer of aluminium oxide.

In other embodiments, the insulator may be formed of a trilayer, for example a sandwich structure wherein the lower and upper sub-layers are formed of the same material. By way of example, the insulator comprises zirconium oxide/aluminium oxide/zirconium oxide, or aluminium oxide/zirconium oxide/aluminium oxide. Such combinations can be advantageous since the materials may be selected for their counterbalanced dielectric constant and breakdown voltage. In yet further embodiments, the insulator may be formed of four or more sub-layers, for example a nano-laminate of alternating layers of aluminium oxide and hafnium oxide. Each sub-layer of a multilayer insulator typically has a thickness of less than 5 nm, and may be less than 2 nm or even less than 1 nm (the total thickness generally being no more than 50 nm as described above).

Another advantage of the present transistor resulting from the “lateral” configuration of the drain contact with respect to the graphene layer structure is that the inventors had found that it is difficult to probe/contact to the drain in a “vertical” configuration whereby the drain is above the graphene. Typically, wire bonding is used to connect the transistor to a circuit and wire bonding a wire to the contact often results in damaging and shorting the tunnel barrier. The positioning of the drain contact in the present transistor permits facile probing of the contact with substantially reduced risk of damage to the insulator layer providing the tunnel junction. This is particularly important for mass manufacture of such devices for commercial production.

The transistor further comprises a gate contact. The gate contact may be provided over the graphene layer structure and separated therefrom by the insulating cap (a so-called “top-gated” configuration). A gate contact may instead be provided under the graphene layer structure and separated therefrom by the substrate (a so-called “back-gated” configuration). As will be appreciated, the gate contact may be provided by a conductive layer of a composite substrate as described herein. Accordingly, the contact is separated from the graphene layer structure by the non-metallic layer of the substrate providing the non-metallic surface upon which the graphene layer structure is provided.

Both top- and back-gated configurations are known in the art such that the relative configuration and location of the gate contact with respect to the conductive channel provided by the graphene layer will be known to a skilled person. Preferably, the source contact is a metal contact preferably comprising one or more of nickel, chromium, titanium, aluminium, platinum, palladium, gold and silver. Similarly, the drain may also preferably be such a metal contact. Other suitable contacts include titanium nitride.

Where the transistor is top-gated, the gate contact is equally preferably a metal contact. Where the transistor is back-gated, a layer of a composite substrate may serve as the gate contact. For example, a silicon layer of a substrate, preferably a doped silicon layer (e.g. having a dopant concentration of from 10¹³ to 10¹⁸ cm⁻³) may serve as the gate contact which is separated from the graphene by a dielectric layer such as a layer of silicon oxide. As will be appreciated for connection into an electronic circuit, the conductive layer separated from the graphene layer structure by the substrate typically comprises a further metal contact. This may be provided on the underside of the substrate in direct contact with the electrically conductive layer, though the electrically conductive layer may comprise a channel extending to a portion of the surface of the substrate upon which a metal contact may be provided (thereby being on the same face of the substrate as the other components of the transistor). In such an embodiment, the further metal contact may be deposited on the conductive surface of the substrate at the same time as depositing the source contact. Alternatively, the “back gate” may be a metal contact which underlies the graphene layer structure and may be separated therefrom by the substrate.

In other embodiments of the present invention, it is preferred that the gate and/or drain contacts are indium tin oxide (ITO) or a further graphene layer structure.

In a further aspect of the present invention, there is provided a method for the manufacture of a transistor, the method comprising:
providing a graphene layer structure having an insulating cap, on a first region of a non-metallic surface of a substrate;
depositing a source contact in contact with a first edge of the graphene layer structure;
forming a continuous layer of an insulator over the source, the insulating cap and at least a second region of the substrate adjacent an opposite, second edge of the graphene;
depositing a drain contact on the continuous layer of insulator over the second region of the substrate, whereby there is a distance of least separation between the drain contact and the graphene layer structure along the second edge of the graphene layer structure and through the insulator;
optionally forming a further insulating layer over the continuous layer of insulator and the drain contact; and
depositing a gate contact on the continuous layer of insulator or, where present, on the further insulating layer, over the graphene layer structure and, laterally, relative to the substrate, between the source and drain contacts, or, wherein the graphene layer structure having an insulating cap is provided over a gate contact, separated therefrom by the substrate.

The method for the manufacture of a transistor may preferably be used in the manufacture of other devices, such as LEDs, OLEDs, solar cells, having integrated transistor functionality. For example, the drain contact may then comprise an LED or OLED layered stack (such stacks being well known in the art) whereby the distance of least separation exists between the graphene layer structure and a charge transport layer of the stack. A metal ohmic contact may then be provided on top of the stack for connection into a circuit.

Preferably, the graphene layer structure is formed by CVD directly on the non-metallic surface of a substrate. CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor. One of the most common precursors for graphene growth is methane though other hydrocarbons may be used. Preferred compounds include those disclosed in UK Patent Application No. 2103041.6 (the contents of which is incorporated herein in its entirety) where it is preferred that the precursor is an organic compound comprising at least two methyl groups (—CH₃). The inventors have found that when forming graphene directly on non-metallic substrates, precursors beyond the traditional hydrocarbons methane and acetylene allow for the formation of even higher quality graphene, and by extension, doped graphene for use in the present invention. Preferably, the precursor is a C₄-C₁₀ organic compound, more preferably the organic compound is branched such that the organic compound has at least three methyl groups. Doped graphene is formed from a carbon-containing precursor which also contains the doping element. Alternatively, a further precursor containing the doping element may be introduced simultaneously with the carbon-containing precursor (and may be carbon-containing itself).

Preferably, the method involves forming graphene by thermal CVD such that decomposition is a result of heating the carbon-containing precursor. Preferably, the CVD reaction chamber used in the method disclosed herein is a cold-walled reaction chamber wherein a heater coupled to the substrate is the only source of heat to the chamber.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the non-metallic surface). Accordingly, such an embodiment involves a “vertical” arrangement whereby the plane containing the precursor entry points is substantially parallel to the plane of the substrate surface.

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470 (which is incorporated herein by reference), very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor. Such a method is particularly preferred for enabling the large-scale industrial manufacture of an array of transistors upon a single common substrate. This is particularly advantageous as this allows for consistent device fabrication with stable properties from one device to the next on a commercial scale. Individual devices may be divided therefrom using conventional means such as dicing.

Consequently, in a particularly preferred embodiment wherein the method of the present invention involves using a method as disclosed in WO 2017/029470, the method comprises:
providing a substrate on a heated susceptor in a CVD reaction chamber, the CVD reaction chamber having a plurality of cooled inlets arranged so that, in use, the inlets are distributed across the non-metallic surface of the substrate and have constant separation from the non-metallic surface of the substrate;
cooling the inlets to less than 100° C. (i.e. so as to cool the precursor);
introducing a carbon-containing precursor in a gas phase and/or suspended in a gas through the inlets and into the CVD reaction chamber; and
heating the susceptor to a temperature of at least 50° C. in excess of a decomposition temperature of the precursor, to provide a thermal gradient between the surface of the substrate and inlets that is sufficiently steep to thereby decompose the precursor and allow the formation of a graphene layer structure from the carbon released from the decomposed precursor;
wherein the constant separation is less than 100 mm, preferably less than 25 mm, even more preferably less than 10 mm.

Preferably, the insulating cap is provided by physical vapour deposition, preferably electron beam deposition or thermal evaporation, more preferably using a mask thereby patterning the insulating cap during deposition. Preferably, the insulating cap is formed of a metal oxide such as alumina, silica, hafnia, titania, yttria, zirconia and/or yttria-stabilised zirconia. The insulating cap may also be formed of silicon nitride. Alumina, hafnia and/or silicon nitride are particularly preferred.

The graphene layer structure having an insulating cap is provided on a first region of a non-metallic surface of a substrate. That is, the first region is defined by the region of the substrate surface upon which the graphene layer structure having an insulating cap is in contact. In particular, where the insulating cap is formed by physical vapour deposition through a mask, thereby defining a first region, the exposed areas of graphene without the insulating cap are preferably etched using plasma etching. As a result, the remaining region(s) of the substrate is re-exposed. Such a method is particularly advantageous since it avoids any “wet” chemistry techniques such as photolithography and/or the use of harsh chemical etchants which can otherwise compromise the graphene quality. Nevertheless, it is also preferred that the transistor is manufactured using photolithography techniques since these typically allow for the manufacture of significantly smaller devices. That is, in some embodiments, the insulating cap is preferably provided on the graphene layer structure by photolithography.

The method comprises depositing a source contact in contact with a first edge of the graphene layer structure. Conventional contact deposition means may be used such as e-beam deposition or thermal evaporation, preferably using a mask.

The method further comprises forming a continuous layer of an insulator over (and directly on) the source, the insulating cap and at least a second region of the substrate adjacent an opposite, second edge of the graphene. The method also comprises depositing a drain contact on the continuous layer of insulator over the second region of the substrate, whereby there is a distance of least separation between the drain contact and the graphene layer structure along the second edge of the graphene layer structure and through the insulator. Preferably, the method further comprises wire bonding to the contacts. Preferably, the method comprises wire bonding a metal wire (e.g. a gold wire) to the drain contact in the second region. That is, the drain contact is preferably wire bonded in a region that is not over the graphene layer structure. As a result, the method is advantageous as there is substantially reduced risk of damaging the thin barrier of the tunnel junction.

In a preferred embodiment, the method also comprises a step of forming a further insulating layer over the continuous layer of insulator and the drain contact. The further insulating layer is particularly preferred where a top gate is subsequently provided. The further insulating layer can provide sufficient thickness for separating the gate from the graphene layer structure whilst simultaneously serving to cover and protect the drain contact (thereby reducing the risk of the gate and drain contacts shorting). Preferably, the thickness of the further insulating layer is from 1 to 50 nm.

Accordingly, it is preferred that the method further comprises depositing a gate contact on the continuous layer of insulator or, where present, on the further insulating layer, over the graphene layer structure. As will be appreciated, a gate contact is provided to modulate current flow through the graphene layer structure between source and drain such that the gate contact will be provided laterally, relative to the surface of the substrate, between the source and drain contacts. Alternatively, the graphene layer structure having an insulating cap is provided over the gate contact, separated therefrom by the substrate. In this case, the gate contact is preferably an electrically conductive layer of the substrate and as such, the gate contact is separated from the graphene layer structure by the non-metallic layer. Equally, the gate contact in the form of an electrically conductive layer of the substrate will at least be provided laterally between the source and drain contacts.

In a particularly preferred embodiment, the continuous layer of insulator is formed by atomic layer deposition (ALD), as is the further insulating layer, if present, to provide a continuous layer. Such a deposition techniques provides an effective means for providing a thin tunnel barrier at an exposed edge of the graphene layer structure. The adjacent insulating cap and substrate provide sufficient nucleation sites to provide conformal growth of the insulator layer within significantly fewer defects at such thin thicknesses relative to that which may be observed when attempting to grow an insulator directly on the surface of graphene (due to the absence of nucleation sites on the surface of high quality graphene, specifically graphene provided directly on the substrate by CVD relative to transferring graphene grown on a sacrificial substrate (e.g. copper) which often introduces material defects).

As described herein, the continuous insulator layer formed by the method comprise multiple sub-layers. In some embodiments, at least the first (lower) sub-layer is formed by ALD, and preferably the subsequent layers, for example in the formation of a trilayer insulator layer, or a nanolaminate. In other embodiments, the method may comprise depositing a seed layer of metal, such as aluminium or titanium, which is then oxidised, to form an aluminium or titanium oxide layer. Such oxidation may occur upon ambient exposure to air, or may occur in embodiments whereby a further metal oxide sub-layer is formed thereon, for example by ALD, and the metal layer is exposed to the oxygen precursor (e.g. oxygen or ozone gas).

### FIGURES

The present invention will now be described further with reference to the following non-limiting Figure, in which:

FIG. 1 is a cross-section of a comparative graphene field effect transistor incorporating a tunnel junction between the graphene and drain.

FIG. 2 is a cross-section of a transistor according to the present invention.

FIG. 3 illustrates a method according to the present invention of forming the transistor shown in FIG. 2.

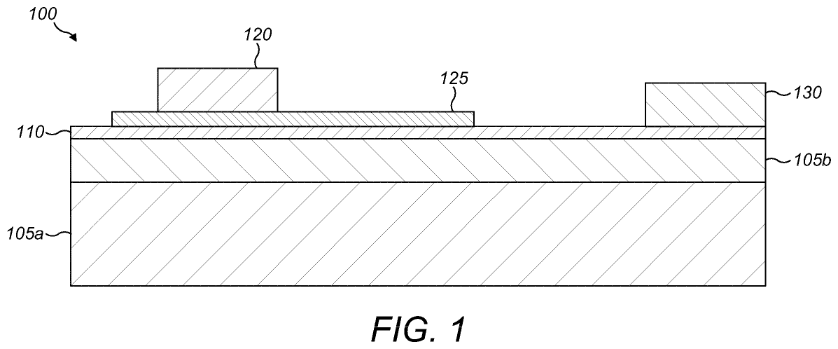

FIG. 1 is a cross-section of a comparative graphene field effect transistor 100. Specifically, the transistor 100 is an example of a back-gated transistor whereby a substrate 105 comprises a silicon layer 105a for connection to an electronic circuit for providing a gate voltage. The substrate 105 comprises an upper silicon oxide layer 105b upon which is provided a graphene layer structure 110, that consists of a single layer of graphene. The graphene 110 is provided on and across the silicon oxide layer 105b by a standard transfer technique which comprises growth of graphene by CVD from methane on a catalytic copper foil substrate, spin coating a polymer across the graphene 110, etching away the copper substrate by suspension in an etching solution. The polymer coated graphene 110 is then placed onto the substrate 105 and the polymer removed by dissolution in an appropriate solvent.

A monolayer of hexagonal boron nitride (h-BN) 125 is then transferred onto the surface of the graphene 110 and a source contact 120 and drain contact 130 are deposited on the h-BN 125 and graphene 110, respectively to form the transistor 100. The h-BN 125 provides a thin tunnel junction separating the graphene 110 from the source contact 120.

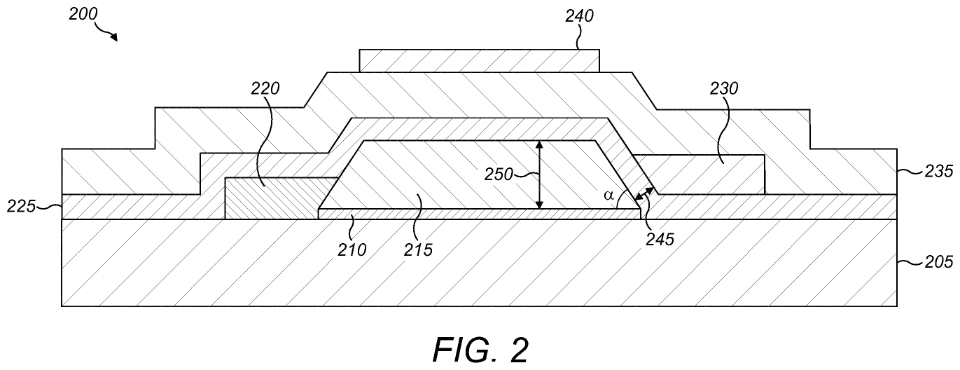

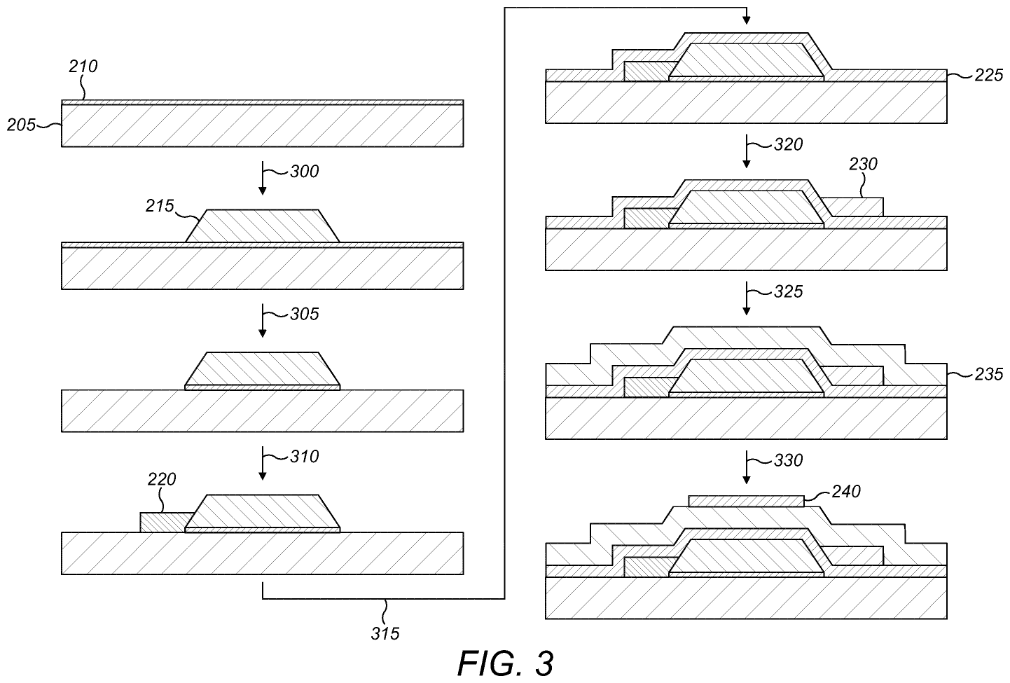

FIG. 2 is a cross-section of a transistor 200 that is obtainable by the method shown in FIG. 3. Transistor 200 comprises a sapphire substrate 205. The transistor 200 comprises a graphene layer structure 210 (a graphene monolayer), having an insulating aluminium oxide cap 215. The cap 215 defines the size and shape of the underlying graphene monolayer 210 and shares a continuous outer edge. The cap 215 has a trapezoidal cross-section whose thickness 250 is about 15 nm wherein the angle of contact a with the graphene 210 is about 45°. The cap 215 may have a rectangular shape perpendicular to the surface of the substrate and graphene 210 (that is from a plan view of the device). Transistor 200 comprises three metal ohmic contacts 220, 230 240. The source contact 220 is in direct contact with a first edge of the graphene layer structure. The drain contact 230 is separated from the graphene layer structure by a distance of least separation 245 from a second edge of the graphene 210. Where the cap 215 has a rectangular shape, the second edge is an opposite parallel edge of the graphene layer structure. However, as will be appreciated, other shapes may be used. For example, contacts 220 and 230 may be positioned across a diameter of a circular graphene 210 and cap 215.

A layer of aluminium oxide 225 about 3 nm thick is in contact with the opposite, second edge of the graphene 210 such that the drain contact 230 is provided in contact with the aluminium oxide 225, and the distance of least separation 245 extends through the insulator 225 and it slightly greater than 3 nm in view of the thickness of the aluminium oxide 225. As a result, the distance of least separation may be achieved by suitable selection of the thickness of insulator layer 225 as described herein. The gate contact 240 is provided over the graphene 210 and is separated therefrom by the insulating cap 215, the aluminium oxide layer 225 and a “gate layer” of aluminium oxide 235 having a thickness of greater than 50 nm, specifically on the gate layer 235. In other embodiments, the gate contact 240 is provided by a conductive layer of the substrate 205 (such as doped silicon), rather than a metal ohmic contact, affording a “back-gated” configuration. Other embodiments may include both gate contacts.

FIG. 3 illustrates a method according to the present invention of forming transistor 200. In a first step, an aluminium oxide insulating cap 215 is deposited through a rectangular mask by evaporation deposition 300 onto the surface of a graphene 210 provided on the surface of a sapphire substrate 205. It is particularly preferred that the graphene 210 is deposited by a method according to WO 2017/029470. The cap 215 protects the underlying portion of the graphene 210 from atmospheric contamination and allows for patterning by plasma etching 305 the exposed portions. A metal source contact 220 is deposited through a mask by e-beam evaporation 310. The contact is deposited on the substrate 205 and, in order to ensure good contact with the thin edge of the etched graphene 210, the source contact 220 is also deposited on the truncated portion of the trapezoidal cap 215.

Subsequently, an aluminium oxide insulator layer 225 is deposited by atomic layer deposition (ALD) 315 to provide a layer on and across the source contact 220, cap 215 and substrate 225. ALD allows for the conformal growth of aluminium oxide having a uniform thickness from the growth surface based on the number of ALD cycles employed. This advantageously allows for the formation of a barrier between the graphene edge and drain contact 230 which is subsequently deposited through a mask by e-beam evaporation 320. Equally, ALD covers the entire surface and encapsulates the intermediate product thereby protecting the entirety of the etched graphene 210 and its edge(s).

A gate layer of aluminium oxide 235 is then also deposited by ALD 325 on and across the aluminium oxide insulator layer 225 and the drain contact 230. Finally, the metal gate contact 240 is deposited through a mask by e-beam evaporation 330 onto the gate layer of aluminium oxide 235 over the graphene 210, cap 215 and insulator layer 225. Additionally, the gate contact 240 is positioned laterally between the source 220 and drain 230 contacts (relative to the surface of the substrate 205) in a conventional manner so as to enable modulation of the electronic properties of the etched graphene 210 and ultimately the current flow from source 220 to drain 230 in the direction of the distance of least separation 245, through the insulator layer 225 providing the tunnel junction.

### EXAMPLES

A transistor was manufactured in accordance with the method shown in FIG. 1. The method comprises growing a layer of graphene on a sapphire substrate is accordance with the techniques disclosed in WO 2017/029470. Then evaporate a 10 nm layer of alumina through a shadow mask onto the graphene to provide an insulating cap having a trapezoidal cross-section. Use an O₂ plasma to etch away the exposed graphene. Evaporate a 10/200 nm Ti/Au contact through a shadow mask on one edge of the graphene channel. Grow a 2 nm alumina layer by ALD over the entire wafer (i.e. across the insulating cap, source contact and exposed substrate surface). Evaporate a 10/200 nm Ti/Au contact through a shadow mask onto the 2 nm ALD alumina at one edge of the graphene channel. Grow a 75 nm alumina layer by ALD over the entire wafer (i.e. across the 2 nm barrier layer and drain contact). Evaporate a 10/200 nm Ti/Au gate contact through a shadow mask over the graphene channel.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “under”, “below”, “beneath”, “lower”, “over”, “above”, “upper” and the like, may be used herein for ease of description to describe one element or feature's relationship to another element(s) or feature(s), primarily in reference to a direction orthogonal to the substantially planar surface of the substrate. It will be understood that the spatially relative terms are intended to encompass different orientations of the device in use or operation in addition to the orientation depicted in the figures. For example, if a device as described herein is turned over, elements described as “under” or “below” other elements or features would then be oriented “over” or “above” the other elements or features. Thus, the example term “under” can encompass both an orientation of over and under. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A transistor comprising:
a graphene layer structure provided on a non-metallic surface of a substrate, the graphene layer structure having an insulating cap;
a source contact provided in contact with a first edge of the graphene layer structure;
an insulator provided in contact with an opposite, second edge of the graphene layer structure;
a drain contact provided in contact with the insulator, whereby there is a distance of least separation between the drain contact and the graphene layer structure along the second edge of the graphene layer structure and through the insulator; and
a gate contact provided (i) over the graphene layer structure and separated therefrom by the insulating cap and/or (ii) under the graphene layer structure and separated therefrom by substrate.

2. The transistor according to claim 1, wherein the distance of least separation is from 1 to 5 nm.

3. The transistor according to claim 1, wherein the insulator is provided as a continuous layer over the source, the insulating cap and at least a portion of the substrate underlying the drain.

4. The transistor according to claim 3, wherein the insulator has a thickness of from 1 to 5 nm.

5. The transistor according to claim 1, wherein the insulator comprises alumina, silica, hafnia, titania, yttria, zirconia and/or yttria-stabilised zirconia.

6. The transistor according to claim 5, wherein the insulator is formed of two sub layers.

7. The transistor according to claim 5, wherein the insulator is formed of three sub layers.

8. The transistor according to claim 7, wherein the lowermost and uppermost sub-layers are formed of alumina or zirconia, and sandwich a middle sub-layer formed of a different insulator.

9. The transistor according to claim 5, wherein the insulator is formed of four or more sub-layers.

10. The transistor according to claim 1, wherein the insulating cap comprises alumina, silica, hafnia, titania, yttria, zirconia, yttria-stabilised zirconia, and/or silicon nitride.

11. The transistor according to claim 1, wherein the insulating cap has a trapezoidal cross-section.

12. The transistor according to claim 1, wherein the source contact, and optionally one or both of the drain and gate contacts, are metal contacts and/or titanium nitride.

13. The transistor according to claim 12, wherein the metal contacts comprise one or more of nickel, chromium, titanium, aluminium, platinum, palladium, gold and silver.

14. The transistor according to claim 12, wherein the drain contact comprises a further graphene layer structure, or is a metal contact.

15. The transistor according to claim 12, wherein the gate contact comprises a further graphene layer structure, or is a metal contact, or is a conductive layer under the graphene layer structure separated therefrom by the substrate.

16. The transistor according to claim 1, wherein the non-metallic surface of the substrate is electrically insulative.

17. A method for the manufacture of a transistor, the method comprising:
providing a graphene layer structure having an insulating cap, on a first region of a non-metallic surface of a substrate;
depositing a source contact in contact with a first edge of the graphene layer structure;
forming a continuous layer of an insulator over the source, the insulating cap and at least a second region of the substrate adjacent an opposite, second edge of the graphene;
depositing a drain contact on the continuous layer of insulator over the second region of the substrate, whereby there is a distance of least separation between the drain contact and the graphene layer structure along the second edge of the graphene layer structure and through the insulator;
optionally forming a further insulating layer over the continuous layer of insulator and the drain contact; and
depositing a gate contact on the continuous layer of insulator or, where present, on the further insulating layer, over the graphene layer structure and, laterally, relative to the substrate, between the source and drain contacts, or, wherein the graphene layer structure having an insulating cap is provided over a gate contact, separated therefrom by the substrate.

18. The method according to claim 17, wherein the graphene layer structure having an insulating cap is provided by evaporation deposition of an insulating material through a mask.

19. The method according to claim 17, wherein the method further comprises wire bonding a metal wire to the drain contact in the second region.

20. The method according to claim 17, wherein the continuous layer of insulator is formed by atomic layer deposition (ALD).
